(19) United States
(12) Patent Application Publication
(10) Pub. No.: US 2020/0105337 A1
(43) Pub. Date: Apr. 2, 2020

(54) MEMORY CELLS AND ARRAYS FOR COMPUTE IN MEMORY COMPUTATIONS

(71) Applicants: Gregory CHEN, Portland, OR (US); Raghavan KUMAR, Hillsoro, OR (US); Huseyin Ekin SUMBUL, Portland, OR (US); Phil KNAG, Hillsboro, OR (US); Ram KRISHNAMURTHY, Portland, OR (US); Sasikanth MANIPATRUNI, Portland, OR (US); Amrita MATHURIYA, Portland, OR (US); Abhishek SHARMA, Hillsboro, OR (US); Ian A. YOUNG, Portland, OR (US)

(72) Inventors: Gregory CHEN, Portland, OR (US); Raghavan KUMAR, Hillsoro, OR (US); Huseyin Ekin SUMBUL, Portland, OR (US); Phil KNAG, Hillsboro, OR (US); Ram KRISHNAMURTHY, Portland, OR (US); Sasikanth MANIPATRUNI, Portland, OR (US); Amrita MATHURIYA, Portland, OR (US); Abhishek SHARMA, Hillsboro, OR (US); Ian A. YOUNG, Portland, OR (US)

(21) Appl. No.: 16/146,759

(22) Filed: Sep. 28, 2018

(51) Int. Cl. G11C 11/412; G11C 11/417; H01L 27/11; H01L 49/02

(52) U.S. Cl. CPC G11C 11/412; H01L 28/60; H01L 27/1104; G11C 11/417

(57) ABSTRACT

Embodiments herein describe techniques for a semiconductor device including a memory cell. The memory cell includes a storage cell and a capacitor having a first electrode and a second electrode. The first electrode and the second electrode may be placed in a metal layer below a metal electrode coupled to one or more transistors of the storage cell. The storage cell is to store a digital value, where a voltage value of an output line of the storage cell is to be determined based on the digital value stored in the storage cell. The second electrode of the capacitor is coupled to the output line of the storage cell. The capacitor is to store a charge based on the voltage value of the output line of the storage cell. Other embodiments may be described and/or claimed.

### FIELD

Embodiments of the present disclosure generally relate to the field of integrated circuits, and more particularly, to memory cells and arrays for compute in memory (CIM) computations.

### BACKGROUND

The background description provided herein is for the purpose of generally presenting the context of the disclosure. Unless otherwise indicated herein, the materials described in this section are not prior art to the claims in this application and are not admitted to be prior art by inclusion in this section.

Compute in memory (CIM) computation may perform certain computations within memory devices, e.g., memory cells or memory arrays. CIM computation may offer many advantages compared to the traditional computer architecture. For example, CIM computation may reduce the energy consumption for data movement between memory devices and logic blocks, improve the efficiency of computation, and increase the effective memory bandwidth. CIM computation may be applied to many current applications such as machine learning or artificial intelligence. In machine learning workloads, data movement between memory devices and logic blocks may consume up to 90% of the overall consumed energy. CIM computation may be applied to improve the efficiency and reduce the energy consumption of the computation for machine learning workloads. However, the current technology for CIM computation may have large memory cells in a memory array, which may consume high power.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIGS. 1(a)-1(d) schematically illustrate various memory cells for compute in memory (CIM) computation, in accordance with various embodiments.

FIGS. 2(a)-2(b) schematically illustrate various memory arrays including CIM memory cells, in accordance with various embodiments.

FIG. 3 illustrates a diagram of a process for forming a CIM memory cell, in accordance with various embodiments.

FIG. 4 schematically illustrates an interposer implementing one or more embodiments of the disclosure, in accordance with some embodiments.

FIG. 5 schematically illustrates a computing device built in accordance with an embodiment of the disclosure, in accordance with some embodiments.

### DETAILED DESCRIPTION

Compute in memory (CIM) computation may perform certain computations within memory devices, e.g., memory cells or memory arrays. For example, memory devices may perform multiply and accumulate (MAC) operations by charge sharing using metal-oxide-metal (MOM) capacitors. MAC operations are widely used in many applications. In some instances, up to 99% of calculations in deep learning are MAC operations used to implement matrix-matrix multiplications. MAC operations performed by a memory device through charge sharing CIM computation may improve the effective bandwidth by simultaneously accessing a large amount of data and calculating the one bit multiplication and accumulation of many partial products on a single wire. In general, CIM computation may offer many advantages, such as reduced energy consumption, or increased memory bandwidth, compared to the traditional von Neumann architecture or compute near memory techniques. However, current process technologies for MOM capacitors may lead to large memory cells in a memory array for CIM computation. Furthermore, MOM capacitors in memory cells for CIM computation devices may be placed in high metal layers, blocking important routing layers for other functions.

In embodiments, when CIM computation is performed, a bit stored in a storage cell, e.g., a static random-access memory (SRAM) bitcell, may be driven onto a capacitor coupled to the bitcell. The capacitors of the memory cells of a memory array may be shorted together to a common output. The resulting voltage on the common output is proportional to an average value of the data stored in the multiple storage cells of the memory array. An analog-to-digital (A/D) converter may be used to convert the resulting voltage on the common output of the memory array to a digital value, which may be an average value of the bits stored in the storage cells of the memory array. The average value generated by the A/D converter may be scaled to a sum of the bits stored in the storage cells of the memory array by multiplying with the number of storage cells of the memory array.

In embodiments, a memory cell may perform CIM computation using a metal-insulator-metal (MIM) capacitor implemented within a memory cell including a storage cell, e.g., a SRAM bitcell. A capacitor may be within a storage cell or a memory cell when the electrodes or plates of the capacitor are placed in locations that are not to occupy any additional area for the layout of the storage cell or the memory cell. For example, the electrodes or plates of a capacitor may be placed below a metal electrode coupled to one or more transistors of the storage cell. Other forms of layouts may be possible as well to place a capacitor within a storage cell, e.g., to place the electrodes or plates of the capacitor next to a metal electrode of a ground voltage (Vss) or a supply voltage (Vcc), so that the overall area occupied by the capacitor and the storage cell is substantially the same as the area occupied by a layout of the storage cell. Embodiments herein may achieve layout density, higher capacitance per-bitcell, and higher resolution by reducing the effects of capacitor mismatch and parasitic. Hence, embodiments herein may improve the throughput and energy efficiency of machine learning chips.

Embodiments herein may present a semiconductor device including a memory cell. The memory cell includes a storage cell and a capacitor having a first electrode and a second electrode. The first electrode and the second electrode may be placed in a metal layer below a metal electrode coupled to one or more transistors of the storage cell. The storage cell is to store a digital value, where a voltage value of an output line of the storage cell is to be determined based on the digital value stored in the storage cell. The second electrode of the capacitor is coupled to the output line of the storage cell. The capacitor is to store a charge based on the voltage value of the output line of the storage cell.

Embodiments herein may present a semiconductor device including a first memory cell and a second memory cell. The first memory cell includes a first storage cell to store a first digital value, and a first capacitor coupled to the first storage cell to have a first charge and a first voltage value. The first charge and the first voltage value are determined based at least on the first digital value. The first memory cell further includes a first selector, where an input line of the first selector is coupled to an electrode of the first capacitor. An output line of the first selector is coupled to a common output shared between the first memory cell and the second first memory cell. A first control line is to control the first selector to be active. The second memory cell includes a second storage cell to store a second digital value, and a second capacitor coupled to the second storage cell to have a second charge and a second voltage value. The second charge and the second voltage value are determined based at least on the second digital value. The second memory cell further includes a second selector, where an input line of the second selector is coupled to an electrode of the second capacitor. An output line of the second selector is coupled to the common output shared between the first memory cell and the second memory cell. A second control line is to control the second selector to be active. The first selector and the second selector share a same control signal for the first control line and the second control line. The first capacitor and the second capacitor have a substantially same capacitance. A voltage value of the common output is an average voltage value of the first voltage value of the first capacitor and the second voltage value of the second capacitor.

In embodiments, a method is presented for forming a semiconductor device. The method includes forming one or more transistors on a substrate for a memory cell to store a digital value into a storage cell of the memory cell. The method further includes forming a capacitor having a first electrode, a second electrode, and a dielectric material between the first electrode and the second electrode. The capacitor is to store a charge based on the digital value stored in the storage cell. The second electrode is coupled to an output line of the storage cell. In addition, the method includes forming a metal electrode coupled to the one or more transistors of the memory cell, wherein the metal electrode is in a metal layer above the first electrode and the second electrode of the capacitor.

In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure. However, the order of description should not be construed to imply that these operations are necessarily order dependent. In particular, these operations may not be performed in the order of presentation.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

As used herein, the term “circuitry” may refer to, be part of, or include an Application Specific Integrated Circuit (ASIC), an electronic circuit, a processor (shared, dedicated, or group), and/or memory (shared, dedicated, or group) that execute one or more software or firmware programs, a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

Implementations of the disclosure may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, zinc oxide or other combinations of group III-V, II-VI, group IV, or semiconducting oxide materials. Although a few examples of materials from which the substrate may be formed are described here, any material that may serve as a foundation upon which a semiconductor device may be built falls within the spirit and scope of the present disclosure.

A plurality of transistors, such as metal-oxide-semiconductor field-effect transistors (MOSFET or simply MOS transistors), may be fabricated on the substrate. In various implementations of the disclosure, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the disclosure may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO2) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type work function metal or N-type work function metal, depending on whether the transistor is to be a PMOS or an NMOS transistor. In some implementations, the gate electrode layer may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a work function that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a work function that is between about 3.9 eV and about 4.2 eV.

In some implementations, when viewed as a cross-section of the transistor along the source-channel-drain direction, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the disclosure, the gate electrode may consist of a combination of U-shaped structures and planar, non-U-shaped structures. For example, the gate electrode may consist of one or more U-shaped metal layers formed atop one or more planar, non-U-shaped layers.

In some implementations of the disclosure, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process operations. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO2), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

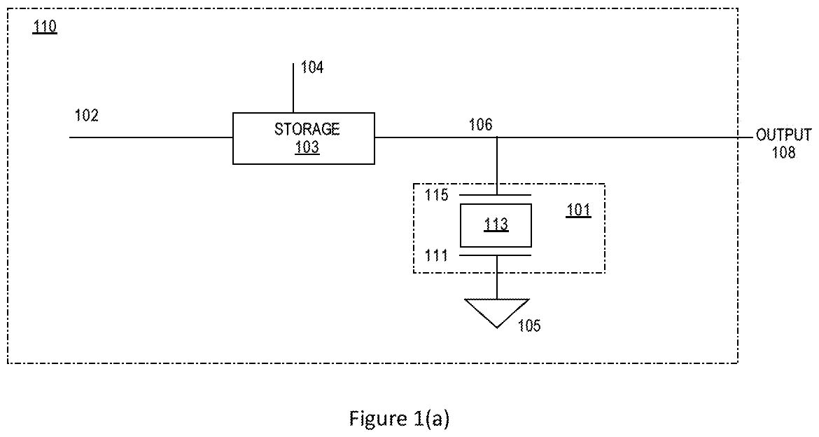

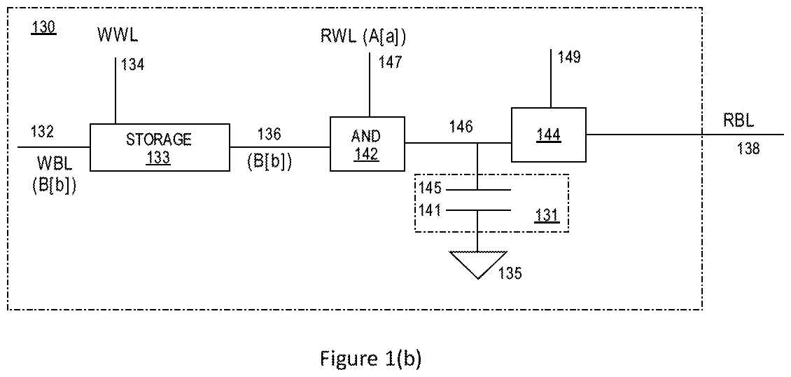

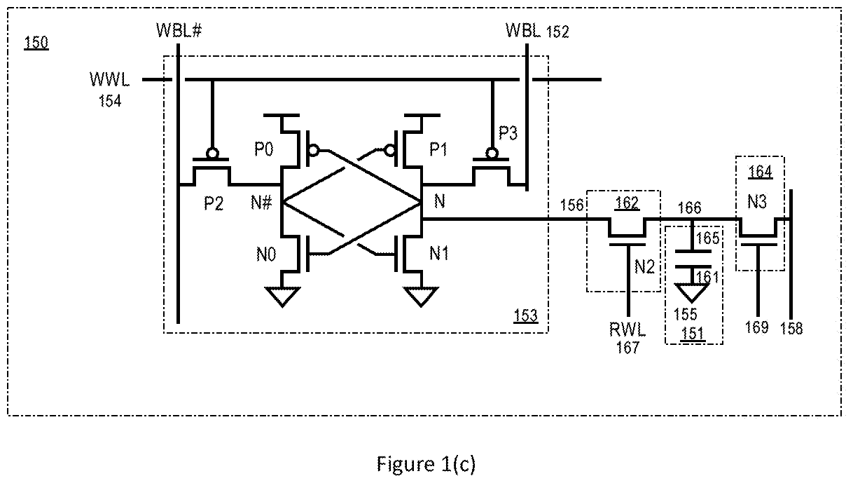

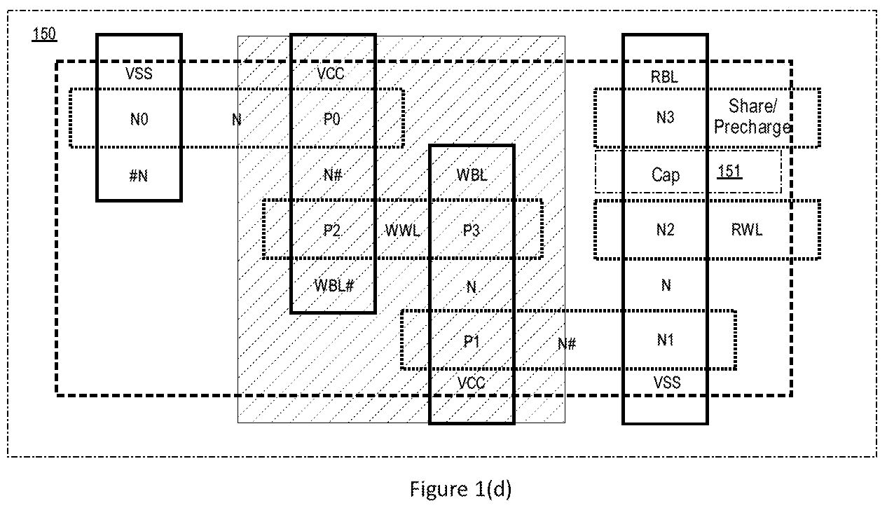

FIGS. 1(a)-1(d) schematically illustrate various memory cells, e.g., a memory cell 110, a memory cell 130, and a memory cell 150, for CIM computation, in accordance with various embodiments. For clarity, features of the memory cell 110, the memory cell 130, and the memory cell 150 may be described below as examples for understanding an example memory cell for CIM computation. It is to be understood that there may be more or fewer components within a memory cell for CIM computation. Further, it is to be understood that one or more of the components within a memory cell for CIM computation, may include additional and/or varying features from the description below, and may include any device that one having ordinary skill in the art would consider and/or refer to as a memory cell for CIM computation.

In embodiments, as shown in FIG. 1(a), the memory cell 110 includes a storage cell 103 coupled to a capacitor 101. The storage cell 103 includes an input line 102, an input line 104, and an output line 106. The capacitor 101 includes a first electrode 111, a second electrode 115, and a dielectric material 113 between the first electrode 111 and the second electrode 115. The output line 106 of the storage cell 103 is coupled to the second electrode 115, and coupled to an output 108 of the memory cell 110. The memory cell 110 may perform CIM computation and may be a part of an integrated circuit for a machine learning classifier or dot-product of two vectors.

In embodiments, the storage cell 103 is to store a digital value. The digital value stored in the storage cell 103 may be based on a signal of the input line 102. The input line 104 may control when a digital value based on a signal of the input line 102 is to be written into the storage cell 103. For example, when the input line 104 has a high voltage, representing a digital 1, a digital value based on a signal of the input line 102 may be written into the storage cell 103. The output line 106 may have a voltage value to be determined based on the digital value stored in the storage cell 103. For example, the output line 106 is to have a first voltage value when the storage cell 103 stores a digital 0, or a second voltage value when the storage cell stores a digital 1.

In embodiments, the capacitor 101 is to store a charge based on the voltage value of the output line 106 of the storage cell 103. The first electrode 111 and the second electrode 115 may be placed in a metal layer below a metal electrode coupled to one or more transistors of the storage cell 103. For example, the first electrode 111 and the second electrode 115 may be placed below a third metal layer. Additionally and alternatively, as shown in more details in FIG. 1(d), the first electrode 111 and the second electrode 115 may be placed in a dielectric layer between two metal layers and below a metal layer for a ground voltage. In some embodiments, the first electrode 111 of the capacitor 101 may be coupled to the ground voltage 105.

In embodiments, the capacitor 101 includes the dielectric material 111 with a dielectric constant that may be higher than 10. The first electrode 111 or the second electrode 115 of the capacitor 101 may include germanium (Ge), cobalt (Co), titanium (Ti), tungsten (W), molybdenum (Mo), gold (Au), platinum (Pt), aluminum (Al), nickel (Ni), copper (Cu), chromium (Cr), hafnium (Hf), indium (In), ruthenium (Ru), iridium (Ir), tantalum (Ta), or an alloy of Ti, W, Mo, Au, Pt, Al, Ni, Cu, Cr, Hf, HfAlN, iridium-tantalum alloy (Ir—Ta), indium-tin oxide (ITO), TaN, TiN, TiAlN, TiW, or InAlO.

In embodiments, as shown in FIG. 1(b), the memory cell 130 includes a storage cell 133 coupled to a capacitor 131. The storage cell 133 includes an input line 132, an input line 134, and an output line 136. The capacitor 131 includes a first electrode 141, a second electrode 145, with a dielectric material between the first electrode 141 and the second electrode 145. The first electrode 141 may be coupled to a ground voltage 135. The output line 136 of the storage cell 133 is coupled to a selector 142. The selector 142 further includes an input line 147 and an output line 146. The output line 146 is coupled to the second electrode 145 of the capacitor 131. In addition, a selector 144 is to have an input line coupled to the second electrode 145, an input line 149, and an output line 138 as the output of the memory cell 130. The memory cell 130 may perform CIM computation and may be a part of an integrated circuit for a machine learning classifier or dot-product of two vectors.

In embodiments, the storage cell 133 is to store a digital value. The digital value stored in the storage cell 133 may be based on a signal of the input line 132. The input line 134 may control when a digital value to be written into the storage cell 133. The output line 136 may have a voltage value to be determined based on the digital value stored in the storage cell 133. For example, the signal of the input line 132 may be a write bit line (WBL) signal representing a bit value of a first number, B[b], while a signal of the input line 134 may be a write word line (WWL) signal. When the WWL signal on the input line 134 is high, the storage cell 133 is selected, and the bit value of B[b] is written into the storage cell 133. In embodiments, the capacitor 131 is to store a charge based on the voltage value of the output line 136 of the storage cell 133. The first electrode 141 and the second electrode 145 may be placed in a metal layer below a metal electrode coupled to one or more transistors of the storage cell 133.

In embodiments, the selector 142 is coupled to the output line 136 of the storage cell 133. The selector 142 further includes the input line 147, which may be a control line with a control input, e.g., a read word line (RWL). The selector 142 includes the output line 146 coupled to the second electrode 145 of the capacitor 131. When the selector 142 is active based on the input line 147, the charge value of the capacitor 131 is to be determined based on the voltage value of the output line 136 of the storage cell 131. For example, the input line 147 may be a control line with a control input representing a bit of a second number, A[a]. When the signal of the input line 132 and the output line 136 of the storage cell 133 represents a bit value of a first number, B[b], the output line 146 of the selector 142 represents a product of the bit of the first number and the bit of the second number, A[a]*B[b]. A voltage of the output line 146 of the selector 142 is determined according to the product A[a]*B[b]. Hence, the memory cell 130 performs CIM multiplication by the selector 142 and the storage cell 133.

In embodiments, another selector 144 is coupled to the selector 142 and coupled to the second electrode 145 of the capacitor 131. The selector 144 is coupled to the output line 146 of the selector 142, and coupled to the second electrode 145 of the capacitor 131. The selector 144 has an input line 149, which may be a control line with a control input, a share or pre-charge line, for the selector 144. Furthermore, the selector 144 has an output line 138, which may be an output, e.g., a read bit line (RBL), of the memory cell 130. The output line 138 of the selector 144 is to have a voltage value when the selector 144 is active, the voltage value of the output line 138 of the selector 144 is to be determined based on the charge stored in the capacitor 131.

In embodiments, the selector 142 or the second selector 144 may be implemented by various means. For example, the selector 142 or the second selector 144 may be a pass transistor. As shown in FIG. 1(c), the selector 142 or the second selector 144 may be a NMOS pass transistor. In some other embodiments, the selector 142 or the second selector 144 may be a PMOS transistor.

The memory cell 150 shown in FIG. 1(c) may be a detailed implementation of the memory cell 130. In detail, the memory cell 150 includes a storage cell 153 coupled to a capacitor 151 through a selector 162, and a selector 164 coupled to the capacitor 151 and an output 158 of the memory cell 150. The storage cell 153, the capacitor 151, the selector 162, and the selector 164 may be examples of the storage cell 133, the capacitor 131, the selector 142, and the selector 144 respectively, as shown in FIG. 1(b).

In embodiments, the storage cell 153 includes an input line 152, an input line 154, and an output line 156. The output line 156 of the storage cell 153 is coupled to the selector 162. The capacitor 151 includes a first electrode 161 coupled to a ground voltage 155, and a second electrode 165. The selector 162 further includes an input line 167 and an output line 166. The output line 166 is coupled to the second electrode 165 of the capacitor 151. A selector 164 is further coupled to an output line 166 of the selector 162 and coupled to the second electrode 165 of the capacitor 151. In addition, the selector 164 is to have an input line 169, and an output line 158 as the output of the memory cell 150.

In embodiments, the storage cell 153 is a static random-access memory (SRAM) cell with 6 transistors, e.g., transistors P0, P1, P2, P3, NO, and N1. In some other embodiments, other storage cell, such as a SRAM cell with 8 transistors, a SRAM cell with 4 transistors, or a SRAM cell with 2 transistors may be used as the storage cell 153 as well. The selector 162 is a NMOS pass transistor N2, and the selector 164 is a NMOS pass transistor N3. In some other embodiments, the selector 162 or the selector 164 may be a PMOS transistor, or a pass gate with both a NMOS transistor and a PMOS transistor.

In embodiments, the selector 162 is coupled to the output line 156 of the storage cell 153. The selector 162 further includes the input line 167, which may be a control line with a control input. When the selector 162 is active based on the input line 167, the charge value of the capacitor 151 is to be determined based on the voltage value of the output line 156 of the storage cell 151. For example, the input line 167 may be a control line with a control input representing a bit of a second number, A[a]. When the signal of the input line 152 and the output line 156 of the storage cell 153 represents a bit value of a first number, B[b], the output line 166 of the selector 162 represents a product of the bit of the first number and the bit of the second number, A[a]*B[b]. A voltage of the output line 166 of the selector 162 is determined according to the product A[a]*B[b]. Hence, the memory cell 150 performs CIM multiplication by the selector 162 and the storage cell 153. The capacitor 151 is to have a charge and a voltage value determined based on the product A[a]*B[b], where B[b] may be a digital value stored in the storage cell 153.

The memory cell 150 shown in FIG. 1(c) may have various layouts. FIG. 1(d) illustrates one layout for the memory cell 150, including the transistors P0, P1, P2, P3, NO, and N1 forming the storage cell 153, the transistor N2 as the selector 162, and the transistor N3 as the selector 164. The capacitor 151, including the first electrode 161 and the second electrode 165, may be placed between the metal electrodes for the transistor N2 and N3. As such placed, the capacitor 151 does not occupy any additional area of the fingerprint compared to a layout for the P0, P1, P2, P3, NO, and N1, N2 and N3, without the capacitor 151. In other words, the layout area occupied by the capacitor 151 is within a layout area for the storage cell 151, the selector 162, and the selector 164. Additionally and alternatively, the capacitor 151 may be placed in a dielectric layer between two metal layers and below a metal layer for a ground voltage Vss. The first electrode 161 of the capacitor 151 may be coupled to the ground voltage Vss. In some embodiments, the interconnects for the transistors P0, P1, P2, P3, NO, and N1 for the storage cell 153, the transistor N2 for the selector 162, the transistor N3 for the selector 162, and the capacitor 151 may be placed below a third metal layer M3 so that higher metal layers may be used to route other functions.

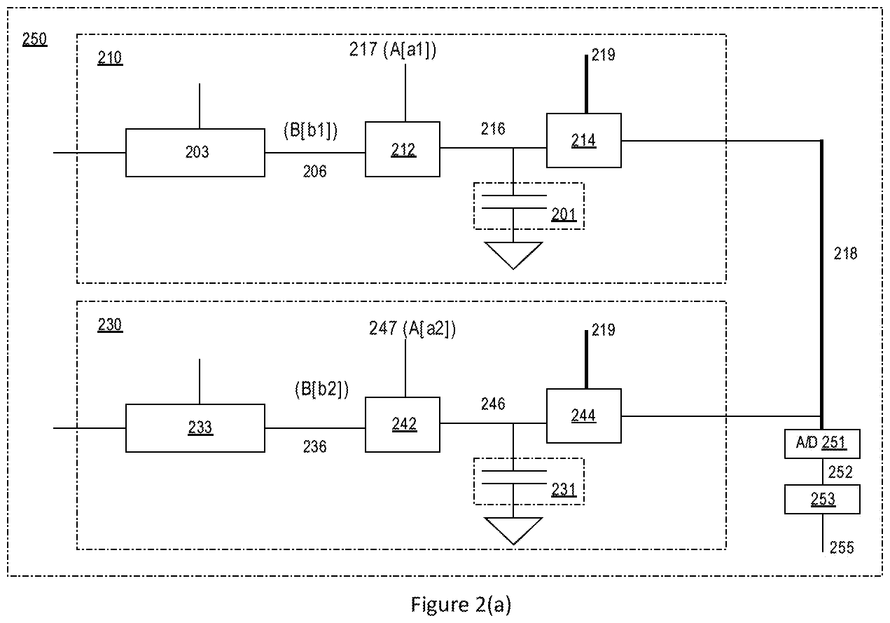

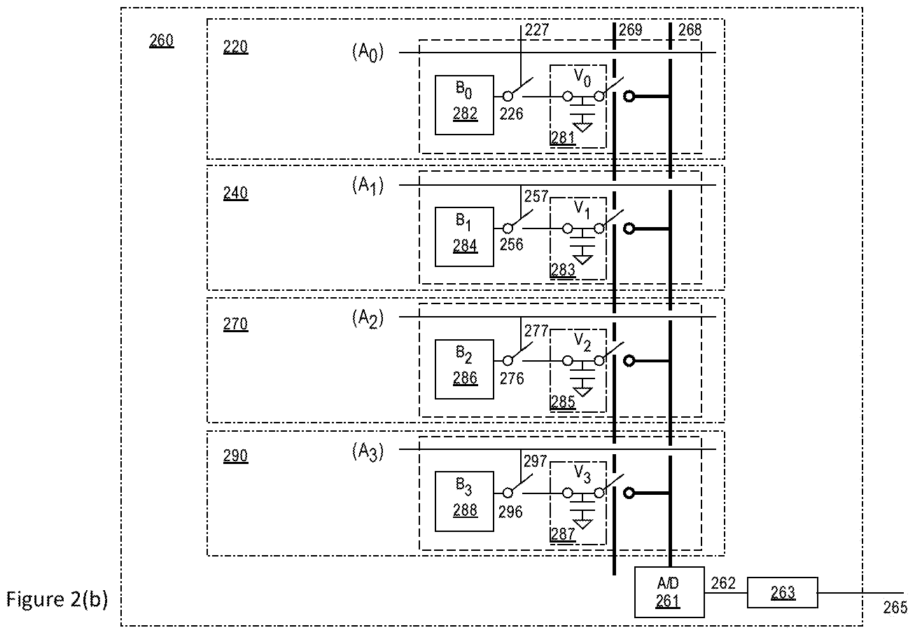

FIGS. 2(a)-2(b) schematically illustrate various memory arrays including CIM memory cells, in accordance with various embodiments. For example, a memory array 250 including a memory cell 210 and a memory cell 230 is shown in FIG. 2(a), and a memory array 260 including a memory cell 220, a memory cell 240, a memory cell 270, and a memory cell 290 is shown in FIG. 2(b). The memory cells, e.g., the memory cell 210, the memory cell 230, the memory cell 220, the memory cell 240, the memory cell 270, and the memory cell 290, may be examples of the memory cell 130 or the memory cell 150, as shown in FIGS. 1(b)-1(d).

In embodiments, as shown in FIG. 2(a), the memory array 250 includes the memory cell 210 and the memory cell 230 sharing an output 218. In detail, the memory cell 210 includes a storage cell 203 coupled to a capacitor 201 through a selector 212, and a selector 214 coupled to the capacitor 201 and the output 218 of the memory cell 210. The memory cell 230 includes a storage cell 233 coupled to a capacitor 231 through a selector 242, and a selector 244 coupled to the capacitor 231 and the output 218 of the memory cell 230. Operations of the memory cell 210 and the memory cell 230 may be similar to the operations described for the memory cell 130 and the memory cell 150 as described for FIGS. 1(b)-1(d).

In embodiments, for the memory cell 210, the storage cell 203 stores a digital value, e.g., B[b1]. The capacitor 201 is coupled to the storage cell 203 to have a first charge and a first voltage value, where the first charge and the first voltage value are determined based at least on the digital value B[b1]. The selector 212 is coupled to the storage cell 203 through an output line 206 of the storage cell 203, and coupled to the capacitor 201 through an output line 216 of the selector 212. The selector 212 has a control input 217 controlled by a digital value, e.g., A[a1]. The first charge and the first voltage value of the capacitor 201 are determined based at least on a first product A[a1]*B[b1]. An input line of the selector 214 is coupled to an electrode of the capacitor 201, and coupled to the output line 216 of the selector 212. The selector 214 is coupled to the output 218. The selector 214 further includes a control line 219 to control the selector 214 to be active.

In embodiments, for the memory cell 230, the storage cell 233 stores a digital value, e.g., B[b2]. The capacitor 231 is coupled to the storage cell 233 to have a second charge and a second voltage value, where the second charge and the second voltage value are determined based at least on the digital value B[b2]. The selector 242 is coupled to the storage cell 233 through an output line 236 of the storage cell 233, and coupled to the capacitor 231 through an output line 246 of the selector 242. The selector 242 has a control input 247 controlled by a digital value, e.g., A[a2]. The second charge and the second voltage value of the capacitor 231 are determined based at least on a second product A[a2]*B[b2]. An input line of the selector 244 is coupled to an electrode of the capacitor 231, and coupled to the output line 246 of the selector 242. The selector 244 is coupled to the output 218. The selector 244 further includes a control line 219 to control the selector 244 to be active.

In embodiments, the selector 244 of the memory cell 230 and the selector 214 of the memory cell 210 share a same control signal, the control line 219. The capacitor 201 and the capacitor 231 have a substantially same capacitance. A voltage value of the output 218 is an average voltage value of the first voltage value of the capacitor 201 and the second voltage value of the capacitor 231.

In embodiments, the memory array 250 may further include an A/D converter 251 coupled to the output 218 to produce a digital output 252 based on the average voltage value, where the digital output 252 is an average of the first product A[a1]*B[b1] and the second product A[a2]*B[b2]. The memory array 250 may further include a scaler 253 coupled to the A/D converter 251 to produce an output 255, which is a sum of the first product A[a1]*B[b1] and the second product A[a2]*B[b2]. The scaler 253 is to generate the output 255 by multiplying the digital output 252 with the number of memory cells, e.g., 2, to produce the sum of the first product A[a1]*B[b1] and the second product A[a2]*B[b2].

In embodiments, as shown in FIG. 2(b), the memory array 260 includes the memory cell 220, the memory cell 240, the memory cell 270, and the memory cell 290. Each of the memory cells, e.g., the memory cell 220, the memory cell 240, the memory cell 270, and the memory cell 290, has a similar configuration, and performs similar operations, e.g., a multiplication function of two one-bit numbers.

For example, the memory cell 220 includes a storage cell 282 coupled to a capacitor 281 through a first selector by way of an output line 226 of the storage cell 282, where the first selector is controlled by a control input 227. In addition, a second selector is coupled to the capacitor 281 and the output 268 of the memory array 260, and is controlled by a control input 269 that is shared among the memory cell 220, the memory cell 240, the memory cell 270, and the memory cell 290. In embodiments, the output of the first selector is determined by a product A0*B0, where one bit B0 is stored in the storage cell 282, and one bit A0 is used to control the control input 227 to the first selector. The capacitor 281 has a first charge and a first voltage value determined based on the product A0*B0.

Similarly, the memory cell 240 includes a storage cell 284 coupled to a capacitor 283 through a first selector by way of an output line 256 of the storage cell 284, where the first selector is controlled by a control input 257. In addition, a second selector is coupled to the capacitor 283 and the output 268 of the memory array 260, and is controlled by the control input 269. In embodiments, the output of the first selector is determined by a product A1*B1, where one bit B1 is stored in the storage cell 284, and one digit A1 is used to control the control input 257 to the first selector. The capacitor 283 has a second charge and a second voltage value determined based on the product A1*B1.

In addition, the memory cell 270 includes a storage cell 286 coupled to a capacitor 285 through a first selector by way of an output line 276 of the storage cell 286, where the first selector is controlled by a control input 277. In addition, a second selector is coupled to the capacitor 285 and the output 268 of the memory array 260, and is controlled by the control input 269. In embodiments, the output of the first selector is determined by a product A2*B2, where one bit B2 is stored in the storage cell 286, and one bit A2 is used to control the control input 277 to the first selector. The capacitor 285 has a third charge and a third voltage value determined based on the product A2*B2.

Furthermore, the memory cell 290 includes a storage cell 288 coupled to a capacitor 287 through a first selector by way of an output line 296 of the storage cell 288, where the first selector is controlled by a control input 297. In addition, a second selector is coupled to the capacitor 287 and the output 268 of the memory array 260, and is controlled by the control input 269. In embodiments, the output of the first selector is determined by a product A3*B3, where one bit B3 is stored in the storage cell 288, and one bit A3 is used to control the control input 297 to the first selector. The capacitor 287 has a fourth charge and a fourth voltage value determined based on the product A3*B3.

In embodiments, the shared control line 269 may turn on the memory cell 220, the memory cell 240, the memory cell 270, and the memory cell 290 at a same time. The capacitor 281, the capacitor 283, the capacitor 285, and the capacitor 287, may have a substantially same capacitance. A voltage value of the output 268 is an average voltage value of the first voltage value of the capacitor 281, the second voltage value of the capacitor 283, the third voltage value of the capacitor 285, and the fourth voltage value of the capacitor 287.

In embodiments, the memory array 260 may further include an A/D converter 261 coupled to the output 268 to produce a digital output 262 based on the average voltage value, where the digital output 262 is an average of the product A0*B0, the product A1*B1, the product A2*B2, and the product A3*B3. The memory array 260 may further include a scaler 263 coupled to the A/D converter 261 to produce an output 265, which is a sum of the product A0*B0, the product A1*B1, the product A2*B2, and the product A3*B3. The scaler 263 is to generate the output 265 by multiplying the digital output 262 with the number of memory cells, e.g., 4, to produce the sum of the product A0*B0, the product A1*B1, the product A2*B2, and the product A3*B3.

As described above for FIG. 2(b), the memory array 260 may perform MAC operations for multiple pairs of one-bit numbers. When a number A or B has multiple bits, the memory array 260 may be used to perform bit-serial operations to calculate the multiplication of numbers with multiple bits, e.g., a dot product of A*B, based on the following pseudo code. The number A and number B are vectors of length ‘len’ with elements of ‘precision a’ bit or ‘precision b’ bit. The descriptions after the sign “#” are comments.

```
Initial code:
for n in range(len): # for each element in vectors
        out += A[n] * B[n] # 8b multiply
Breaking out bit precision from each loop:
for n in range(len): # for each element in vectors
        for pa in range(precision_a): # for each bit in each element in A
                for pb in range(precision_b) # for each bit in
                each element of B
                        out += (A[n][ap] * B[n][bp]) << (pa + pb)
                        # perform 1b multiply and accumulate
Re-ordering loops for bit-serial operation:
for pa in range(precision_a):  # for each bit in each element in A
        for pb in range(precision_b)  # for each bit in each
        element of B
for n in range(len): # for each element in vector A
                        # out += (scalar dot product calculated with
                        CIM) << (pa + pb)
out += (A[n][pa] * B[n][pb]) << (pa + pb)
```

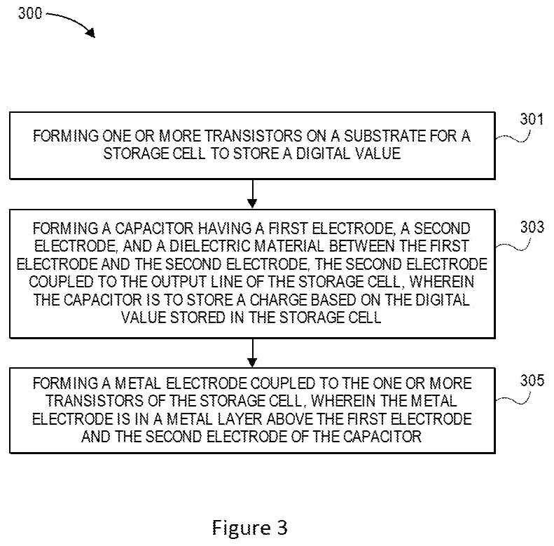

FIG. 3 illustrates a diagram of a process 300 for forming a CIM memory cell, in accordance with various embodiments. In embodiments, the process 300 may be applied to form the memory cell 110, the memory cell 130, the memory cell 150, as shown in FIGS. 1(a)-1(d), or the memory cells in the memory array 250 or the memory array 260, as shown in FIGS. 2(a)-2(b).

At block 301, the process 300 may include forming one or more transistors on a substrate for a memory cell to store a digital value into a storage cell of the memory cell. For example, the process 300 may include forming the transistors P0, P1, P2, P3, NO, N1, N2, and N3 on a substrate for the memory cell 150 to store a digital value into the storage cell 153, as shown in FIGS. 1(c)-1(d).

At block 303, the process 300 may include forming a capacitor having a first electrode, a second electrode, and a dielectric material between the first electrode and the second electrode, the second electrode coupled to an output line of the storage cell, wherein the capacitor is to store a charge based on the digital value stored in the storage cell. For example, the process 300 may include forming the capacitor 151 having the electrode 161, the electrode 165, and a dielectric material between the electrode 161 and the electrode 165, the electrode 165 is coupled to the output line 156 of the storage cell 153, wherein the capacitor 151 is to store a charge based on the digital value stored in the storage cell 153, as shown in FIGS. 1(c)-1(d).

At block 305, the process 300 may include forming a metal electrode coupled to the one or more transistors of the storage cell, wherein the metal electrode is in a metal layer above the first electrode and the second electrode of the capacitor. For example, the process 300 may include forming the metal electrode read bit line (RBL) coupled to the transistor N3 of the memory cell 150, wherein the metal electrode RBL is in a metal layer above the first electrode and the second electrode of the capacitor 151, as shown in FIGS. 1(c)-1(d).

In addition, the process 300 may include additional operations to form other layers, e.g., ILD layers, encapsulation layers, insulation layers, not shown.

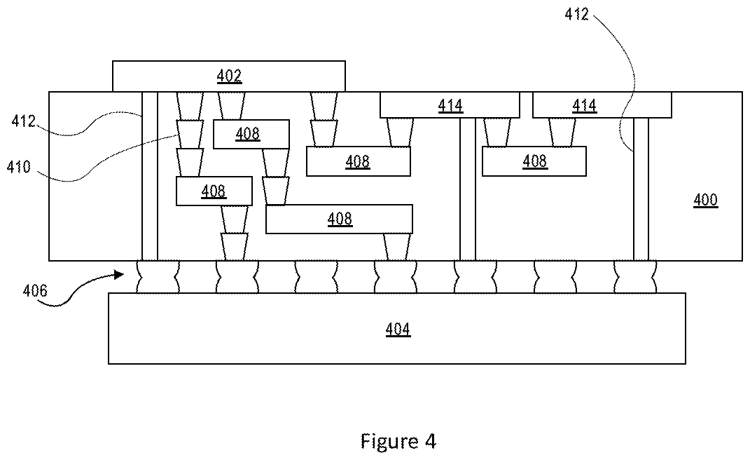

FIG. 4 schematically illustrates an interposer 400 implementing one or more embodiments of the disclosure, in accordance with some embodiments. The interposer 400 is an intervening substrate used to bridge a first substrate 402 to a second substrate 404. The first substrate 402 may be, for instance, a substrate support for a memory cell, e.g., the memory cell 110, the memory cell 130, the memory cell 150, as shown in FIGS. 1(a)-1(d), or the memory cells in the memory array 250 or the memory array 260, as shown in FIGS. 2(a)-2(b), or a memory cell formed according to the process 300, as shown in FIG. 3. The second substrate 404 may be, for instance, a memory module, a computer motherboard, or another integrated circuit die. For example, the second substrate 404 may be a memory module including the memory cell 110, the memory cell 130, the memory cell 150, as shown in FIGS. 1(a)-1(d), or the memory cells in the memory array 250 or the memory array 260, as shown in FIGS. 2(a)-2(b). Generally, the purpose of an interposer 400 is to spread a connection to a wider pitch or to reroute a connection to a different connection. For example, an interposer 400 may couple an integrated circuit die to a ball grid array (BGA) 406 that can subsequently be coupled to the second substrate 404. In some embodiments, the first and second substrates 402/404 are attached to opposing sides of the interposer 400. In other embodiments, the first and second substrates 402/404 are attached to the same side of the interposer 400. And in further embodiments, three or more substrates are interconnected by way of the interposer 400.

The interposer 400 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 408 and vias 410, including but not limited to through-silicon vias (TSVs) 412. The interposer 400 may further include embedded devices 414, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 400.

In accordance with embodiments of the disclosure, apparatuses or processes disclosed herein may be used in the fabrication of interposer 400.

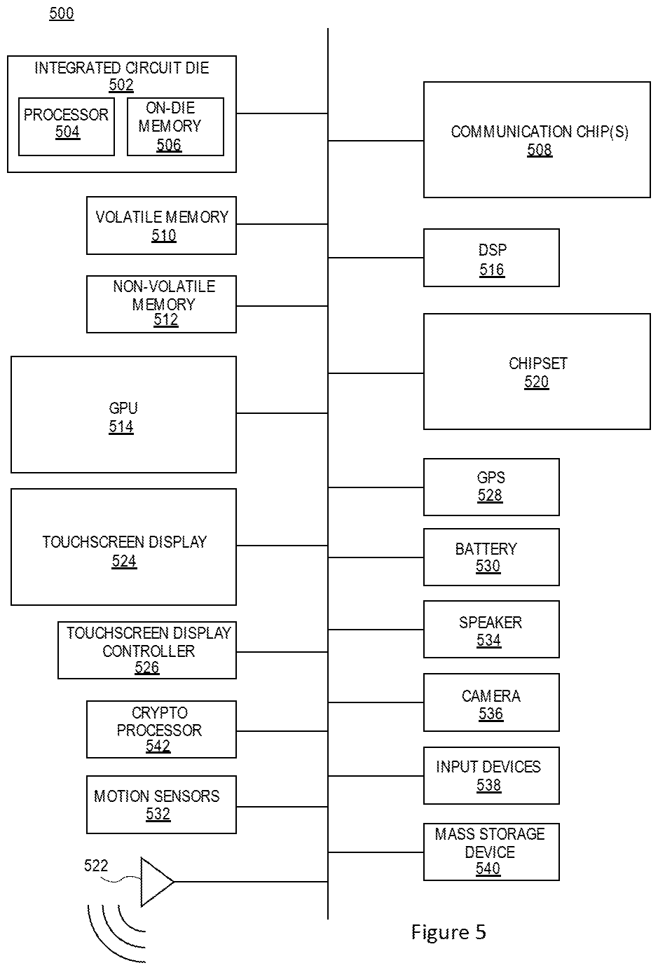

FIG. 5 illustrates a computing device 500 in accordance with one embodiment of the disclosure. The computing device 500 may include a number of components. In one embodiment, these components are attached to one or more motherboards. In an alternate embodiment, some or all of these components are fabricated onto a single system-on-a-chip (SoC) die, such as a SoC used for mobile devices. The components in the computing device 500 include, but are not limited to, an integrated circuit die 502 and at least one communications logic unit 508. In some implementations the communications logic unit 508 is fabricated within the integrated circuit die 502 while in other implementations the communications logic unit 508 is fabricated in a separate integrated circuit chip that may be bonded to a substrate or motherboard that is shared with or electronically coupled to the integrated circuit die 502. The integrated circuit die 502 may include a processor 504 as well as on-die memory 506, often used as cache memory, which can be provided by technologies such as embedded DRAM (eDRAM), or SRAM. For example, the on-die memory 506 may include the memory cell 110, the memory cell 130, the memory cell 150, as shown in FIGS. 1(a)-1(d), or the memory cells in the memory array 250 or the memory array 260, as shown in FIGS. 2(a)-2(b), or a memory cell formed according to the process 300, as shown in FIG. 3.

In embodiments, the computing device 500 may include a display or a touchscreen display 524, and a touchscreen display controller 526. A display or the touchscreen display 524 may include a FPD, an AMOLED display, a TFT LCD, a micro light-emitting diode (μLED) display, or others. For example, the touchscreen display 524 may include the memory cell 110, the memory cell 130, the memory cell 150, as shown in FIGS. 1(a)-1(d), or the memory cells in the memory array 250 or the memory array 260, as shown in FIGS. 2(a)-2(b), or a memory cell formed according to the process 300, as shown in FIG. 3.

Computing device 500 may include other components that may or may not be physically and electrically coupled to the motherboard or fabricated within a SoC die. These other components include, but are not limited to, volatile memory 510 (e.g., dynamic random access memory (DRAM), non-volatile memory 512 (e.g., ROM or flash memory), a graphics processing unit 514 (GPU), a digital signal processor (DSP) 516, a crypto processor 542 (e.g., a specialized processor that executes cryptographic algorithms within hardware), a chipset 520, at least one antenna 522 (in some implementations two or more antenna may be used), a battery 530 or other power source, a power amplifier (not shown), a voltage regulator (not shown), a global positioning system (GPS) device 528, a compass, a motion coprocessor or sensors 532 (that may include an accelerometer, a gyroscope, and a compass), a microphone (not shown), a speaker 534, a camera 536, user input devices 538 (such as a keyboard, mouse, stylus, and touchpad), and a mass storage device 540 (such as hard disk drive, compact disk (CD), digital versatile disk (DVD), and so forth). The computing device 500 may incorporate further transmission, telecommunication, or radio functionality not already described herein. In some implementations, the computing device 500 includes a radio that is used to communicate over a distance by modulating and radiating electromagnetic waves in air or space. In further implementations, the computing device 500 includes a transmitter and a receiver (or a transceiver) that is used to communicate over a distance by modulating and radiating electromagnetic waves in air or space.

The communications logic unit 508 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communications logic unit 508 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Infrared (IR), Near Field Communication (NFC), Bluetooth, derivatives thereof, as well as any other wireless protocols that are designated as 3G, 4G, 5G, and beyond. The computing device 500 may include a plurality of communications logic units 508. For instance, a first communications logic unit 508 may be dedicated to shorter range wireless communications such as Wi-Fi, NFC, and Bluetooth and a second communications logic unit 508 may be dedicated to longer range wireless communications such as GPS, EDGE, GPRS, CDMA, WiMAX, LTE, Ev-DO, and others.

The processor 504 of the computing device 500 includes one or more devices, such as transistors. The term “processor” may refer to any device or portion of a device that processes electronic data from registers and/or memory to transform that electronic data into other electronic data that may be stored in registers and/or memory. The communications logic unit 508 may also include one or more devices, such as transistors.

In further embodiments, another component housed within the computing device 500 may contain one or more devices, such as DRAM, that are formed in accordance with implementations of the current disclosure, e.g., the memory cell 110, the memory cell 130, the memory cell 150, as shown in FIGS. 1(a)-1(d), or the memory cells in the memory array 250 or the memory array 260, as shown in FIGS. 2(a)-2(b), or a memory cell formed according to the process 300, as shown in FIG. 3.

In various embodiments, the computing device 500 may be a laptop computer, a netbook computer, a notebook computer, an ultrabook computer, a smartphone, a dumbphone, a tablet, a tablet/laptop hybrid, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 500 may be any other electronic device that processes data.

Some non-limiting Examples are provided below.

Example 1 may include a semiconductor device, comprising: a memory cell including: a storage cell to store a digital value, wherein a voltage value of an output line of the storage cell is to be determined based on the digital value stored in the storage cell; and a capacitor having a first electrode and a second electrode, the second electrode coupled to the output line of the storage cell, wherein the capacitor is to store a charge based on the voltage value of the output line of the storage cell, and the first electrode and the second electrode are placed in a metal layer below a metal electrode coupled to one or more transistors of the storage cell.

Example 2 may include the semiconductor device of example 1 and/or some other examples herein, wherein the first electrode or the second electrode of the capacitor includes germanium (Ge), cobalt (Co), titanium (Ti), tungsten (W), molybdenum (Mo), gold (Au), platinum (Pt), aluminum (Al), nickel (Ni), copper (Cu), chromium (Cr), hafnium (Hf), indium (In), ruthenium (Ru), iridium (Ir), tantalum (Ta), or an alloy of Ti, W, Mo, Au, Pt, Al, Ni, Cu, Cr, Hf, HfAlN, iridium-tantalum alloy (Ir—Ta), indium-tin oxide (ITO), TaN, TiN, TiAlN, TiW, or InAlO.

Example 3 may include the semiconductor device of example 1 and/or some other examples herein, wherein the capacitor includes a dielectric material with a dielectric constant higher than 10, the dielectric material is between the first electrode and the second electrode of the capacitor.

Example 4 may include the semiconductor device of example 1 and/or some other examples herein, wherein the first electrode and the second electrode of the capacitor are placed below a third metal layer.

Example 5 may include the semiconductor device of example 1 and/or some other examples herein, wherein the first electrode and the second electrode are placed in a dielectric layer between two metal layers and below a metal layer for a ground voltage, and the first electrode of the capacitor is coupled to the ground voltage.

Example 6 may include the semiconductor device of example 1 and/or some other examples herein, wherein the storage cell further includes a first input line and a second input line, the first input line controls to write the digital value of the second input line into the storage cell.

Example 7 may include the semiconductor device of example 6 and/or some other examples herein, wherein the storage cell includes a static random-access memory (SRAM) cell with 8 transistors, a SRAM cell with 6 transistors, a SRAM cell with 4 transistors, or a SRAM cell with 2 transistors.

Example 8 may include the semiconductor device of example 6 and/or some other examples herein, wherein the memory cell is a part of an integrated circuit for a machine learning classifier or dot-product of two vectors.

Example 9 may include the semiconductor device of example 1 and/or some other examples herein, wherein the output line of the storage cell is to have a first voltage value when the storage cell stores a digital 0, or a second voltage value when the storage cell stores a digital 1.

Example 10 may include the semiconductor device of example 1 and/or some other examples herein, further comprising: a selector, wherein an input line of the selector is coupled to the second electrode of the capacitor, and an output line of the selector is to have a voltage value when the selector is active, the voltage value of the output line of the selector is to be determined based on the charge stored in the capacitor.

Example 11 may include the semiconductor device of example 10 and/or some other examples herein, wherein the selector is a first selector, and the memory cell further includes a second selector with an input line, a control line, and an output line, the input line of the second selector is coupled to the output line of the storage cell, the output line of the second selector is coupled to the second electrode of the capacitor, and wherein when the second selector is active based on the control line of the second selector, the charge value of the capacitor is to be determined based on the voltage value of the output line of the storage cell.

Example 12 may include the semiconductor device of example 11 and/or some other examples herein, wherein the voltage value of the output line of the storage cell is determined by a first bit, and the control line of the second selector represents a second bit, and the output line of the second selector is determined based on a product of the first bit and the second bit.

Example 13 may include the semiconductor device of example 11 and/or some other examples herein, wherein the first selector or the second selector is a pass transistor.

Example 14 may include the semiconductor device of example 13 and/or some other examples herein, wherein the first selector or the second selector is a NMOS pass transistor or a PMOS pass transistor.

Example 15 may include a semiconductor device, comprising: a first memory cell including: a first storage cell to store a first digital value; a first capacitor coupled to the first storage cell to have a first charge and a first voltage value, wherein the first charge and the first voltage value are determined based at least on the first digital value; and a first selector, wherein an input line of the first selector is coupled to an electrode of the first capacitor, an output line of the first selector is coupled to a common output, and a first control line is to control the first selector to be active; and a second memory cell including: a second storage cell to store a second digital value; a second capacitor coupled to the second storage cell to have a second charge and a second voltage value, wherein the second charge and the second voltage value are determined based at least on the second digital value; and a second selector, wherein an input line of the second selector is coupled to an electrode of the second capacitor, an output line of the second selector is coupled to the common output, and a second control line is to control the second selector to be active; and wherein the first selector and the second selector share a same control signal for the first control line and the second control line, the first capacitor and the second capacitor have a substantially same capacitance, and a voltage value of the common output is an average voltage value of the first voltage value of the first capacitor and the second voltage value of the second capacitor.

Example 16 may include the semiconductor device of example 15 and/or some other examples herein, further comprising: an analog-to-digital (A/D) converter coupled to the common output to produce a digital output based on the average voltage value, wherein the digital output is an average of the first digital value and the second digital value.

Example 17 may include the semiconductor device of example 16 and/or some other examples herein, further comprising: a scaler coupled to the A/D converter to produce a sum of the first digital value and the second digital value based on the average of the first digital value and the second digital value.

Example 18 may include the semiconductor device of example 15 and/or some other examples herein, wherein the first memory cell further includes an additional selector of the first memory cell coupled to the first storage cell and the first capacitor, the additional selector of the first memory cell has a control input controlled by a third digit value, and the first charge and the first voltage value of the first capacitor are determined based at least on a first product of the first digital value and the third digit value; the second memory cell further includes an additional selector of the second memory cell coupled to the second storage cell and the second capacitor, the additional selector of the second memory cell has a control input controlled by a fourth digit value, and the second charge and the second voltage value of the second capacitor are determined based at least on a second product of the second digital value and the fourth digit value; and the voltage value of the common output is an average voltage value of the first voltage value of the first capacitor determined based at least on the first product and the second voltage value of the second capacitor determined based at least on the second product.

Example 19 may include the semiconductor device of example 15 and/or some other examples herein, further comprising: one or more additional memory cells, wherein a memory cell of the one or more additional memory cells includes: a storage cell to store a digital value of the memory cell; a capacitor coupled to the storage cell to have a charge and a voltage value, wherein the charge and the voltage value of the capacitor are determined based at least on the digital value of the memory cell; and a selector, wherein an input line of the selector is coupled to an electrode of the capacitor, an output line of the selector is coupled to the common output, and a control line is to control the selector to be active; and wherein the capacitor, the first capacitor, and the second capacitor have the substantially same capacitance; the selector, the first selector, and the second selector share the same control signal for the control line, the first control line, and the second control line; the voltage value of the common output is an average voltage value of the first voltage value of the first capacitor, the second voltage value of the second capacitor, and the voltage value of the capacitor of the memory cell for the one or more memory cells.

Example 20 may include the semiconductor device of example 19 and/or some other examples herein, wherein the first memory cell further includes an additional selector of the first memory cell coupled to the first storage cell and the first capacitor, the additional selector of the first memory cell has a control input controlled by a third digit value, and the first charge and the first voltage value of the first capacitor are determined based at least on a first product of the first digital value and the third digit value; the second memory cell further includes an additional selector of the second memory cell coupled to the second storage cell and the second capacitor, the additional selector of the second memory cell has a control input controlled by a fourth digit value, and the second charge and the second voltage value of the second capacitor are determined based at least on a second product of the second digital value and the fourth digit value; and the memory cell of the one or more additional memory cells further includes an additional selector of the memory cell coupled to the storage cell and the capacitor of the memory cell, the additional selector of the memory cell has a control input controlled by an additional digit value of the memory cell, and the charge and the voltage value of the capacitor are determined based at least on an additional product of the digital value of the memory cell and the additional digit value of the memory cell; and the voltage value of the common output is an average voltage value of the first voltage value of the first capacitor determined based on the first product, the second voltage value of the second capacitor determined based on the second product, and the voltage value of the capacitor of the memory cell determined based on the additional product of the one or more memory cells.

Example 21 may include the semiconductor device of example 20 and/or some other examples herein, further comprising: an analog-to-digital (A/D) converter coupled to the common output to produce a digital output, wherein the digital output is an average of the first product, the second product, and the additional product of the one or more memory cells; and a scaler coupled to the A/D converter to produce a sum of the first product, the second product, and the additional product of the one or more memory cells.

Example 22 may include the semiconductor device of example 20 and/or some other examples herein, wherein the semiconductor device is a part of a computing device selected from the group consisting of a wearable device or a mobile computing device, the wearable device or the mobile computing device including one or more of an antenna, a touchscreen controller, a display, a battery, a processor, an audio codec, a video codec, a power amplifier, a global positioning system (GPS) device, a compass, a Geiger counter, an accelerometer, a gyroscope, a speaker, and a camera coupled with the memory device.

Example 23 may include a method for forming a semiconductor device, comprising: forming one or more transistors on a substrate for a memory cell to store a digital value into a storage cell of the memory cell; forming a capacitor having a first electrode, a second electrode, and a dielectric material between the first electrode and the second electrode, the second electrode coupled to an output line of the storage cell, wherein the capacitor is to store a charge based on the digital value stored in the storage cell; and forming a metal electrode coupled to the one or more transistors of the memory cell, wherein the metal electrode is in a metal layer above the first electrode and the second electrode of the capacitor.

Example 24 may include the method of example 23 and/or some other examples herein, wherein the first electrode and the second electrode of the capacitor are placed below a third metal layer, or placed in a dielectric layer between two metal electrodes of the storage cell, or below a metal layer for a ground.

Example 25 may include the method of example 23 and/or some other examples herein, wherein a dielectric constant of the dielectric material is higher than 10.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated implementations, including what is described in the Abstract, is not intended to be exhaustive or to limit the embodiments of the present disclosure to the precise forms disclosed. While specific implementations and examples are described herein for illustrative purposes, various equivalent modifications are possible within the scope of the present disclosure, as those skilled in the relevant art will recognize.

These modifications may be made to embodiments of the present disclosure in light of the above detailed description. The terms used in the following claims should not be construed to limit various embodiments of the present disclosure to the specific implementations disclosed in the specification and the claims. Rather, the scope is to be determined entirely by the following claims, which are to be construed in accordance with established doctrines of claim interpretation.

What is claimed is:

1. A semiconductor device, comprising:
a memory cell including:
a storage cell to store a digital value, wherein a voltage value of an output line of the storage cell is to be determined based on the digital value stored in the storage cell; and
a capacitor having a first electrode and a second electrode, the second electrode coupled to the output line of the storage cell, wherein the capacitor is to store a charge based on the voltage value of the output line of the storage cell, and the first electrode and the second electrode are placed in a metal layer below a metal electrode coupled to one or more transistors of the storage cell.

2. The semiconductor device of claim 1, wherein the first electrode or the second electrode of the capacitor includes germanium (Ge), cobalt (Co), titanium (Ti), tungsten (W), molybdenum (Mo), gold (Au), platinum (Pt), aluminum (Al), nickel (Ni), copper (Cu), chromium (Cr), hafnium (Hf), indium (In), ruthenium (Ru), iridium (Ir), tantalum (Ta), or an alloy of Ti, W, Mo, Au, Pt, Al, Ni, Cu, Cr, Hf, HfAlN, iridium-tantalum alloy (Ir—Ta), indium-tin oxide (ITO), TaN, TiN, TiAlN, TiW, or InAlO.

3. The semiconductor device of claim 1, wherein the capacitor includes a dielectric material with a dielectric constant higher than 10, the dielectric material is between the first electrode and the second electrode of the capacitor.

4. The semiconductor device of claim 1, wherein the first electrode and the second electrode of the capacitor are placed below a third metal layer.

5. The semiconductor device of claim 1, wherein the first electrode and the second electrode are placed in a dielectric layer between two metal layers and below a metal layer for a ground voltage, and the first electrode of the capacitor is coupled to the ground voltage.

6. The semiconductor device of claim 1, wherein the storage cell further includes a first input line and a second input line, the first input line controls to write the digital value of the second input line into the storage cell.

7. The semiconductor device of claim 6, wherein the storage cell includes a static random-access memory (SRAM) cell with 8 transistors, a SRAM cell with 6 transistors, a SRAM cell with 4 transistors, or a SRAM cell with 2 transistors.

8. The semiconductor device of claim 6, wherein the memory cell is a part of an integrated circuit for a machine learning classifier or dot-product of two vectors.

9. The semiconductor device of claim 1, wherein the output line of the storage cell is to have a first voltage value when the storage cell stores a digital 0, or a second voltage value when the storage cell stores a digital 1.

10. The semiconductor device of claim 1, further comprising:
a selector, wherein an input line of the selector is coupled to the second electrode of the capacitor, and an output line of the selector is to have a voltage value when the selector is active, the voltage value of the output line of the selector is to be determined based on the charge stored in the capacitor.

11. The semiconductor device of claim 10, wherein the selector is a first selector, and the memory cell further includes a second selector with an input line, a control line, and an output line, the input line of the second selector is coupled to the output line of the storage cell, the output line of the second selector is coupled to the second electrode of the capacitor, and wherein when the second selector is active based on the control line of the second selector, the charge value of the capacitor is to be determined based on the voltage value of the output line of the storage cell.

12. The semiconductor device of claim 11, wherein the voltage value of the output line of the storage cell is determined by a first bit, and the control line of the second selector represents a second bit, and the output line of the second selector is determined based on a product of the first bit and the second bit.

13. The semiconductor device of claim 11, wherein the first selector or the second selector is a pass transistor.

14. The semiconductor device of claim 13, wherein the first selector or the second selector is a NMOS pass transistor or a PMOS pass transistor.

15. A semiconductor device, comprising:
a first memory cell including:
a first storage cell to store a first digital value;
a first capacitor coupled to the first storage cell to have a first charge and a first voltage value, wherein the first charge and the first voltage value are determined based at least on the first digital value; and
a first selector, wherein an input line of the first selector is coupled to an electrode of the first capacitor, an output line of the first selector is coupled to a common output, and a first control line is to control the first selector to be active; and
a second memory cell including:
a second storage cell to store a second digital value;
a second capacitor coupled to the second storage cell to have a second charge and a second voltage value, wherein the second charge and the second voltage value are determined based at least on the second digital value; and
a second selector, wherein an input line of the second selector is coupled to an electrode of the second capacitor, an output line of the second selector is coupled to the common output, and a second control line is to control the second selector to be active; and
wherein the first selector and the second selector share a same control signal for the first control line and the second control line, the first capacitor and the second capacitor have a substantially same capacitance, and a voltage value of the common output is an average voltage value of the first voltage value of the first capacitor and the second voltage value of the second capacitor.

16. The semiconductor device of claim 15, further comprising:
an analog-to-digital (A/D) converter coupled to the common output to produce a digital output based on the average voltage value, wherein the digital output is an average of the first digital value and the second digital value.

17. The semiconductor device of claim 16, further comprising:
a scaler coupled to the A/D converter to produce a sum of the first digital value and the second digital value based on the average of the first digital value and the second digital value.

18. The semiconductor device of claim 15, wherein the first memory cell further includes an additional selector of the first memory cell coupled to the first storage cell and the first capacitor, the additional selector of the first memory cell has a control input controlled by a third digit value, and the first charge and the first voltage value of the first capacitor are determined based at least on a first product of the first digital value and the third digit value;
the second memory cell further includes an additional selector of the second memory cell coupled to the second storage cell and the second capacitor, the additional selector of the second memory cell has a control input controlled by a fourth digit value, and the second charge and the second voltage value of the second capacitor are determined based at least on a second product of the second digital value and the fourth digit value; and
the voltage value of the common output is an average voltage value of the first voltage value of the first capacitor determined based at least on the first product and the second voltage value of the second capacitor determined based at least on the second product.

19. The semiconductor device of claim 15, further comprising:
one or more additional memory cells, wherein a memory cell of the one or more additional memory cells includes:
a storage cell to store a digital value of the memory cell;
a capacitor coupled to the storage cell to have a charge and a voltage value, wherein the charge and the voltage value of the capacitor are determined based at least on the digital value of the memory cell; and
a selector, wherein an input line of the selector is coupled to an electrode of the capacitor, an output line of the selector is coupled to the common output, and a control line is to control the selector to be active; and
wherein the capacitor, the first capacitor, and the second capacitor have the substantially same capacitance; the selector, the first selector, and the second selector share the same control signal for the control line, the first control line, and the second control line; the voltage value of the common output is an average voltage value of the first voltage value of the first capacitor, the second voltage value of the second capacitor, and the voltage value of the capacitor of the memory cell for the one or more memory cells.

20. The semiconductor device of claim 19,
wherein the first memory cell further includes an additional selector of the first memory cell coupled to the first storage cell and the first capacitor, the additional selector of the first memory cell has a control input controlled by a third digit value, and the first charge and the first voltage value of the first capacitor are determined based at least on a first product of the first digital value and the third digit value;
the second memory cell further includes an additional selector of the second memory cell coupled to the second storage cell and the second capacitor, the additional selector of the second memory cell has a control input controlled by a fourth digit value, and the second charge and the second voltage value of the second capacitor are determined based at least on a second product of the second digital value and the fourth digit value; and
the memory cell of the one or more additional memory cells further includes an additional selector of the memory cell coupled to the storage cell and the capacitor of the memory cell, the additional selector of the memory cell has a control input controlled by an additional digit value of the memory cell, and the charge and the voltage value of the capacitor are determined based at least on an additional product of the digital value of the memory cell and the additional digit value of the memory cell; and
the voltage value of the common output is an average voltage value of the first voltage value of the first capacitor determined based on the first product, the second voltage value of the second capacitor determined based on the second product, and the voltage value of the capacitor of the memory cell determined based on the additional product of the one or more memory cells.

21. The semiconductor device of claim 20, further comprising:
an analog-to-digital (A/D) converter coupled to the common output to produce a digital output, wherein the digital output is an average of the first product, the second product, and the additional product of the one or more memory cells; and
a scaler coupled to the A/D converter to produce a sum of the first product, the second product, and the additional product of the one or more memory cells.

22. The semiconductor device of claim 20, wherein the semiconductor device is a part of a computing device selected from the group consisting of a wearable device or a mobile computing device, the wearable device or the mobile computing device including one or more of an antenna, a touchscreen controller, a display, a battery, a processor, an audio codec, a video codec, a power amplifier, a global positioning system (GPS) device, a compass, a Geiger counter, an accelerometer, a gyroscope, a speaker, and a camera coupled with the memory device.

23. A method for forming a semiconductor device, comprising:
forming one or more transistors on a substrate for a memory cell to store a digital value into a storage cell of the memory cell;
forming a capacitor having a first electrode, a second electrode, and a dielectric material between the first electrode and the second electrode, the second electrode coupled to an output line of the storage cell, wherein the capacitor is to store a charge based on the digital value stored in the storage cell; and
forming a metal electrode coupled to the one or more transistors of the memory cell, wherein the metal electrode is in a metal layer above the first electrode and the second electrode of the capacitor.

24. The method of claim 23, wherein the first electrode and the second electrode of the capacitor are placed below a third metal layer, or placed in a dielectric layer between two metal electrodes of the storage cell, or below a metal layer for a ground.

25. The method of claim 23, wherein a dielectric constant of the dielectric material is higher than 10.
